(19) United States
(12) Patent Application Publication
(10) Pub. No.: US 2023/0304750 A1
(43) Pub. Date: Sep. 28, 2023

(54) HEAT SINK WITH REMOVABLE INSERTS

(71) Applicant: NLIGHT, INC., Camas, WA (US)

(72) Inventors: Mark J. DEFRANZA, Ridgefield, WA (US); Bryce TOKMAKIAN, Portland, OR (US); Eric MARTIN, Vancouver, WA (US); Manoj Kanskar, Portland, OR (US)

(73) Assignee: NLIGHT, INC., Camas, WA (US)

(21) Appl. No.: 18/122,638

(22) Filed: Mar. 16, 2023

Related U.S. Application Data
(60) Provisional application No. 63/322,588, filed on Mar. 22, 2022.

(51) Int. Cl. F28F 9/26; F28F 21/08; F28F 21/04; F28D 15/02; H01S 5/024

(52) U.S. Cl. CPC F28F 9/26; F28F 21/085; F28F 21/04; F28D 15/0275; H01S 5/02423; F28F 2275/14; F28F 2280/02

(57) ABSTRACT

Various embodiments provide apparatuses, systems, and methods related to a heat sink with one or more removable inserts. Respective inserts may include one or more fins that define one or more channels for flow of cooling fluid. The fins may be formed of a composite material that is different than a material of the heat sink body. Other embodiments may be described and/or claimed.

### CROSS REFERENCE TO RELATED APPLICATIONS

This application is a non-provisional of, and claims priority benefit to, U.S. Provisional Application Ser. No. 63/322,588, filed on Mar. 22, 2022, which is incorporated by reference herein in its entirety.

### STATEMENT OF GOVERNMENT FUNDING

This invention was made with Government support under contract #FA9451-18-C-0030 awarded by the U.S. Department of the Air Force. The Government has certain rights in the invention.

### FIELD

Embodiments of the present invention relate generally to the technical field of heat sinks, and more particularly to a heat sink with removable inserts.

### BACKGROUND

The background description provided herein is for the purpose of generally presenting the context of the disclosure. Work of the presently named inventors, to the extent it is described in this background section as well as aspects of the description that may not otherwise qualify as prior art at the time of filing, is neither expressly nor impliedly admitted as prior art against the present disclosure. Unless otherwise indicated herein, the approaches described in this section are not prior art to the claims in the present disclosure and are not admitted to be prior art by inclusion in this section.

In liquid-cooled laser diode packages, the removal of the “diode waste heat” may be a limiting factor in the determination of the laser diode junction temperature, and ultimately the laser performance.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIGS. 1a and 1b illustrate an example of a heat sink with removable inserts, in accordance with various embodiments.

FIG. 2 depicts an example of a removable insert, in accordance with various embodiments.

FIG. 3 depicts an alternative view of a removable insert, in accordance with various embodiments.

FIG. 4 depicts an alternative view of a removable insert, in accordance with various embodiments.

FIG. 5 depicts an alternative view of a removable insert, in accordance with various embodiments.

FIG. 6 depicts an alternative view of a removable insert, in accordance with various embodiments.

FIG. 7 depicts an alternative view of a removable insert, in accordance with various embodiments.

FIG. 8 depicts an example of diode junction temperature versus thermal conductivity of a fin in a removable insert, in accordance with various embodiments.

FIG. 9 depicts an example of test data related to optical power and voltage data of a laser diode package that includes a heat sink with a removable insert, in accordance with various embodiments.

FIG. 10 depicts an example of test data related to spectral data of a laser diode package that includes a heat sink with a removable insert, in accordance with various embodiments.

FIG. 11 depicts an example of test data related to wavelength change versus current of two laser diode packages, in accordance with various embodiments.

FIG. 12 depicts an example of test data related to slope efficiency rollover versus current of two laser diode packages, in accordance with various embodiments.

### DETAILED DESCRIPTION

In the following detailed description, reference is made to the accompanying drawings that form a part hereof wherein like numerals designate like parts throughout, and wherein embodiments that may be practiced are shown by way of illustration. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about” generally refer to being within +/−10% of a target value. Unless otherwise specified, the use of the ordinal adjectives “first,” “second,” “third,” etc., to describe a common object, merely indicate that different instances of like objects are being referred to, and are not intended to imply that the objects so described must be in a given sequence, either temporally, spatially, in ranking, or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous.

As noted, in liquid-cooled laser diode packages, the removal of diode waste heat may be desirable. Generally, the waste heat may be delivered to a liquid-coolant flow channel within the body of the heat sink. In legacy heat sink packages, the heat sink body may have included one or more machined fin structures that form channels through which the liquid coolant would flow. Heat may have been transferred from the laser diodes through the body of the heat sink and, particularly, the fin structures to the liquid coolant, which would then flow from the heat sink to remove heat.

Because the fins used in legacy heat sink packages were integral elements of the heat sink body, the fins would be formed of the same material as the heat sink body. Typically, for weight reduction and cost reasons, the heat sink body would be formed of aluminum. Typically, aluminum has a thermal conductivity on the order of approximately 190 Watts per meter-Kelvin (W/m-K). This relatively low thermal conductivity may not be optimized for heat transfer characteristics for the fins.

Embodiments herein relate to the use of a removable insert that may have more desirable heat transfer characteristics than the above-described legacy heat sink packages. Specifically, the removable insert may include one or more fins formed of a composite material with a higher thermal conductivity. One or more such removable inserts may be placed within a cavity of the heat sink body. As such, the weight and cost benefits of aluminum may still be realized in the heat sink body, while improved thermal characteristics may be provided by the fins of the removable insert.

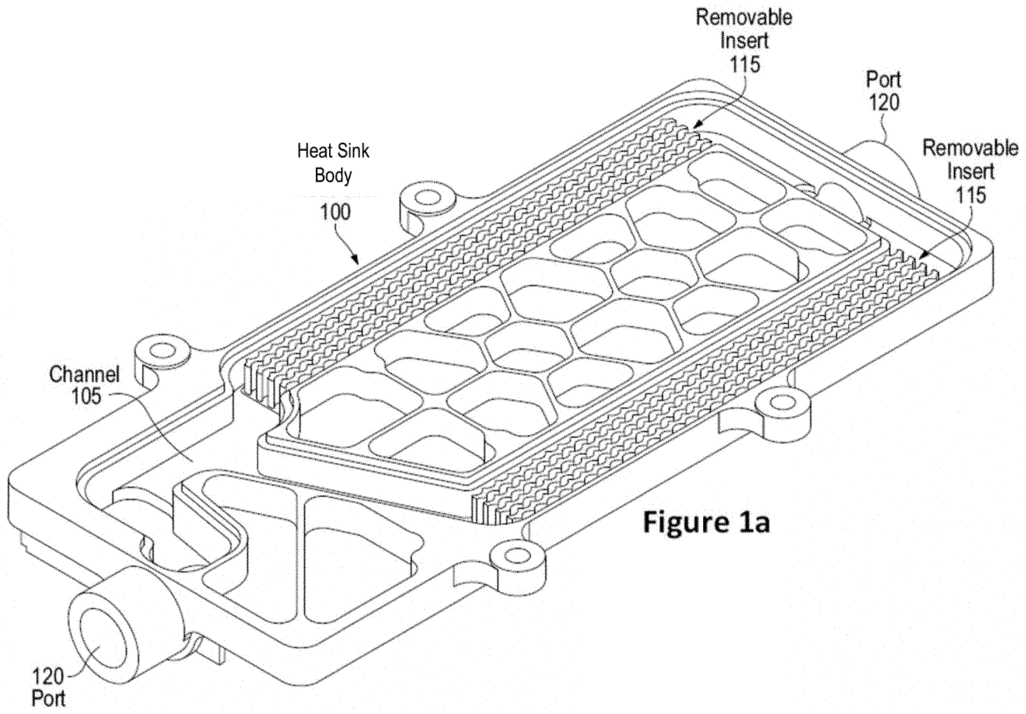

FIGS. 1a and 1b (collectively “FIG. 1”) illustrate an example of a heat sink with removable inserts, in accordance with various embodiments. Specifically, FIG. 1 depicts views from opposing sides of the heat sink (for example, a “top” view and a “bottom” view).

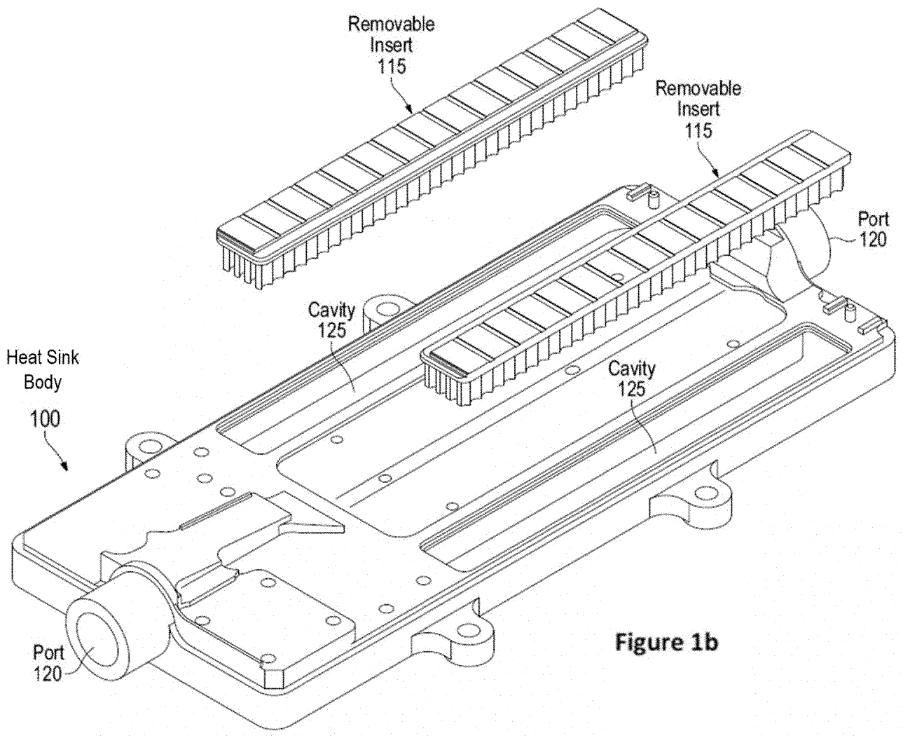

The heat sink may include a heat sink body 100, which may be formed of aluminum or some other lightweight material. The heat sink body 100 may have two or more ports 120 through which liquid coolant may enter and exit the heat sink body 100. The liquid coolant may be, for example, water, dielectric fluids, mineral oils, refrigerants such as R-134, water with ethylene or propylene glycol, water with corrosion or biological inhibitors, and/or some other fluid option. The heat sink body 100 may include one or more channels 105 through which the liquid coolant may flow between the ports 120. The heat sink body 100 may further include one or more cavities 125, into which one or more removable inserts 115 may be placed. Further details of the removable inserts 115 are provided below with respect to FIG. 2.

It will be understood that the embodiment of FIG. 1 is intended as an example embodiment, and other embodiments may vary. For example, other embodiments may include additional ports, additional channels, channels arranged in a different configuration, a different number of cavities 125 and/or inserts 115, etc. It will be noted, particularly with respect to FIG. 1a, that the heat sink body includes a number of hollowed-out portions, which may be present to save weight and/or cost. The particular configuration of these hollowed-out portions may vary in other embodiments.

FIG. 2 depicts an example of a removable insert 115, in accordance with various embodiments. The removable insert may include a plurality of fins 130 that are coupled with a first side of a mounting plate 135. A second side of the mounting plate 135 may be coupled with a plurality of laser diodes 201. Specifically, the mounting plate 135 may include a plurality of mounting plate segments 140, and respective ones of the laser diodes 201 may be mounted with the respective mounting plate segment.

In embodiments, the laser diodes 201 may be configured to generate between approximately 1 and approximately 100 Watts (W) of power. Only four laser diodes 201 are depicted in FIG. 2 for the sake of discussion herein. However, in some embodiments, the removable insert 115 may be configured to couple with between one and 20 laser diodes, dependent on the type of laser diode used, the type of material used for components of the removable insert, the use case to which the system will be put, etc. For example, in some embodiments, the removable insert 115 may be configured to couple with more than 20 laser diodes 201.

As shown, the mounting plate 135 may include a plurality of mounting plate segments 140, upon which respective ones of the laser diodes 201 may be mounted. As shown, the segments 140 may be structured as raised elements with cutouts or divisions between respective ones of the segments 140. One purpose of this structure may be to provide a visual aid for alignment of the laser diodes 201 when mounting the diodes 201 to the mounting plate 135. In other embodiments, the cutouts may act as a solder outflow-blockage mechanism.

The fins 130 may function as described above, and they may provide one or more channels through which the cooling liquid may flow when the removable insert is positioned within the heat sink body 100. In some embodiments, although four fins are depicted in FIG. 2, a removable insert 115 may have between three and approximately 50 fins. The number of fins 130 may be varied based on the use case to which the heat sink will be put, the dimensions of the removable insert 115, the materials used for the fins 130, and/or other considerations.

The mounting plate 135 may serve one or more functions when inserted into the heat sink body 100. Specifically, the mounting plate 135 may provide a mount for the laser diodes 201, as described above. Additionally, in some embodiments the mounting plate may serve as a sealing element for the cavity 125 when the removable insert 115 is inserted into the heat sink body 100. For example, the mounting plate 135 may include an element such as a rubber gasket (not shown in FIG. 2) that provides a waterproof seal when the mounting plate 135 is positioned in the cavity 125 of heat sink body 100. Such a seal may prevent leakage of the liquid coolant from the heat sink when the coolant is flowing within the channel 105.

As noted above, one advantage provided by the removable insert 115 is that the fins 130 may be formed of a material that is different than a material of the heat sink body 100. Specifically, the fins 130 may be formed of a material with a higher thermal conductivity than the aluminum that may be used to form the heat sink body 100. In one embodiment, such a material may be copper, which may have a thermal conductivity on the order of approximately 390 W/m-K. In other embodiments, the fins 130 may additionally or alternatively be formed of a composite material such as a material that includes copper and diamond, a material that includes aluminum and diamond, a material that includes aluminum and graphite, and/or some other material with a relatively high thermal conductivity (e.g., above approximately 200 W/m-K). In some embodiments, respective ones of the fins 130 may include a plurality of such materials, for example having different layers of different materials or composite materials with a relatively high thermal conductivity. In some embodiments, different ones of the fins 130 may be formed of different materials or composite materials with a relatively high thermal conductivity. The specific materials used may be based on factors such as the amount of thermal energy that may be required to be removed by the removable insert 115, the specific configuration of laser diodes 201 coupled with the removable insert 115, or some other factor. It will be appreciated that, as described above, the removable insert 115 may provide advantages and that the fins 130 with the relatively high thermal conductivity may be more efficient in removing heat provided by the laser diodes 201 than, for example, legacy packages that may have used a relatively low-thermal-conductivity material.

In some embodiments, the mounting plate 135 may be formed of a same material, or a different material, than used for the fins 130. In one embodiment, the mounting plate 135 may be formed of a material with a relatively high thermal conductivity such as ceramic or diamond. In other embodiments, the mounting plate 135 may be formed of a metal such as copper or aluminum. In other embodiments, the mounting plate 135 may be formed of a composite material such as copper/diamond or another of the composite materials described above. Additionally or alternatively, the mounting plate 135 may be, or may include, graphite. In general, the selection of the material used for the mounting plate 135 may be based on a coefficient of thermal expansion of the material of the fins 130, and a coefficient of thermal expansion of a material of the mounting plate and a coefficient of thermal expansion of the fins 135. Specifically, it may be desirable to ensure that the two coefficients are compatible with one another to ensure structural integrity of the removable insert 115. More generally, the material of the mounting plate 135 may be selected based on a material with the highest thermal conductivity, and a thermal expansion coefficient that is compatible with the coefficient of the fins 130. In some embodiments, it may be desirable for the material of the mounting plate 135 to be electrically insulating as well for the sake of electrically insulating the various laser diodes 201 from one another.

As may be seen in FIG. 2, the removable insert 115 may include a length L, a width W, and a height H. In some embodiments, the length L may be in a range between approximately 10 millimeters (mm) and approximately 150 mm. The width W may be in a range between approximately 5 mm and 25 mm. The overall height H of the removable insert 115 may be at or under approximately 10 mm. In some embodiments the height of the fins 130 may be between approximately 1 mm and 5 mm. It will be understood that these dimensions are example dimensions for some embodiments of this disclosure, and other embodiments may be larger or smaller in one or more dimensions than described. The specific dimensions may be based on, for example, the use case to which the heat sink or laser diodes 201 will be put, the type of material used for the fins 130 or for the mounting plate 135, the number of laser diodes 201, or one or more other factors or considerations.

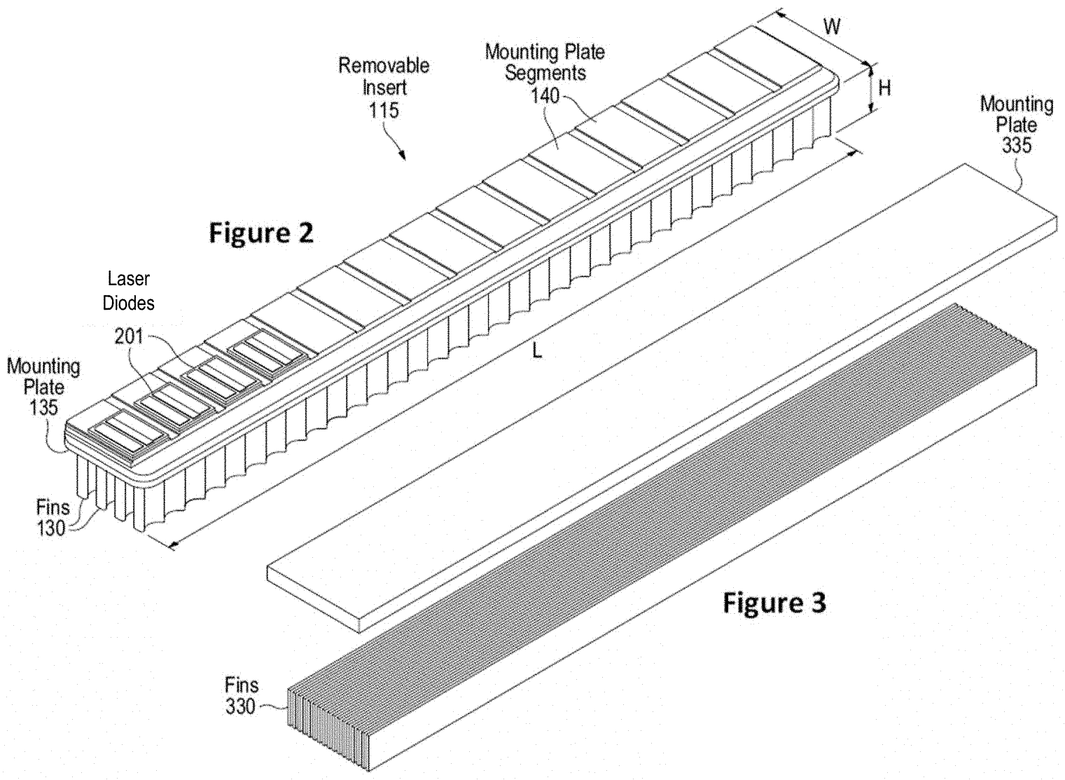

FIG. 3 depicts an alternative view of a removable insert, in accordance with various embodiments. Specifically, FIG. 3 is intended to show how a removable insert such as removable insert 115 may be formed. FIG. 3 depicts a mounting plate 335, and a number of fins 330, which may be respectively similar to, and share one or more characteristics with, mounting plate 135 and fins 130. Specifically, as shown, the fins 330 may be formed separately from the mounting plate 335, and separately from one another 330. For example, the fins 330 may be stamped, molded, machined, deposited, sintered, or formed in some other manner. The fins 330 may then be coupled to the mounting plate 335. Such coupling may include or be based on, for example, soldering, brazing, or some other manner of joining such that the fins 330 are thermally and physically coupled with the mounting plate 335.

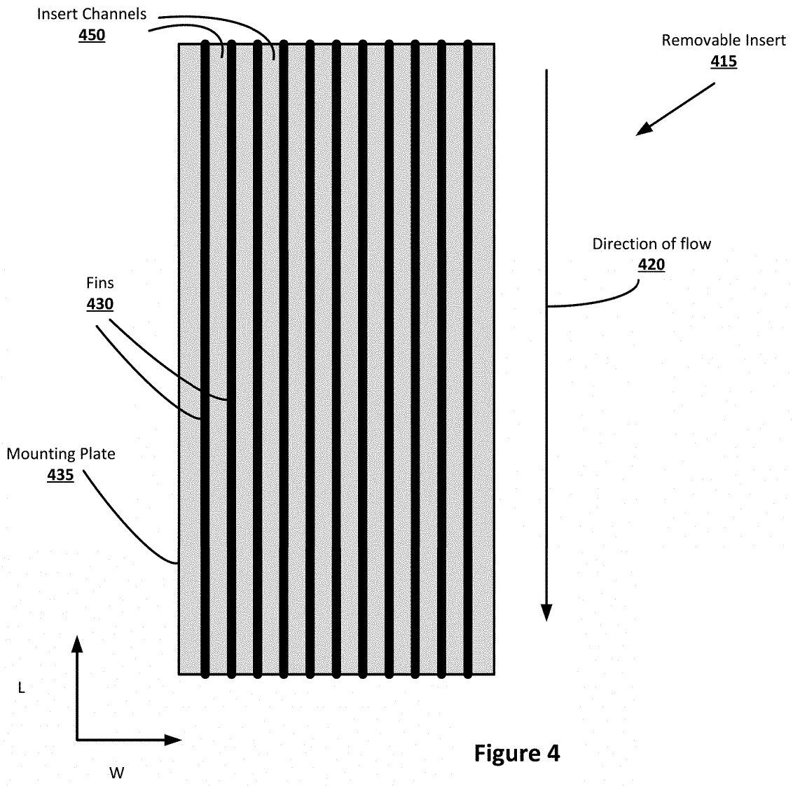

Although the removable inserts depicted in FIGS. 1-3 include, for example, fins 330 with a generally flat shape and profile or fins 130 with a slightly wave-shaped profile, in other embodiments the fins, and their arrangement with respect to the mounting plate, may differ. For example, FIG. 4 depicts an alternative view of a removable insert 415, in accordance with various embodiments. The removable insert 415 of FIG. 4 may have a structure similar to that of the removable insert that would result in coupling the fins 330 with the mounting plate 335 of FIG. 3. Generally, the view of FIG. 4 may be a “bottom up” view of the removable insert 415, such that one is looking at the mounting plate 435 through the insert channels 450 formed by the fins 430. The length L and width W of removable insert 415 are as indicated.

As noted, the removable insert 415 may include fins 430 and mounting plate 435, which may be similar to, and share one or more characteristics with, fins 130/330, and mounting plate 135/335, respectively. As may be seen, the fins 430 may have a generally flat profile, and be arranged parallel to one another to form a plurality of insert channels 450. The liquid coolant may flow from, for example, channel 105 through insert channels 450 as indicated by the direction of flow 420.

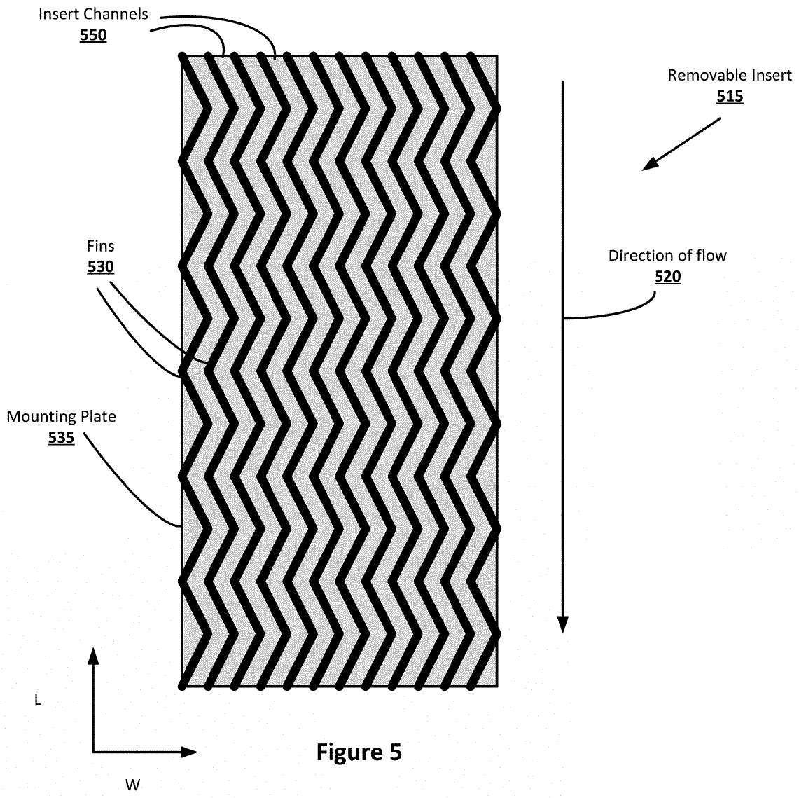

FIG. 5 depicts an alternative view of a removable insert 515, in accordance with various embodiments. The view of FIG. 5 may be similar to the view of FIG. 4, as described above. The removable insert 515 may include fins 530 and mounting plate 535, which may be similar to other fins and/or mounting plates described herein. In this embodiment, rather than having generally linear fins (such as may be seen, for example, in FIG. 4), the fins 530 may have a generally zigzag profile. Such a profile may provide a zigzag pattern for the insert channels 550 through which the liquid coolant may flow in accordance with the direction of flow 520. The zigzag pattern may increase the overall length of the insert channels 550, and therefore in some embodiments may increase the amount of thermal energy removed from laser diodes that are coupled with the removable insert 515.

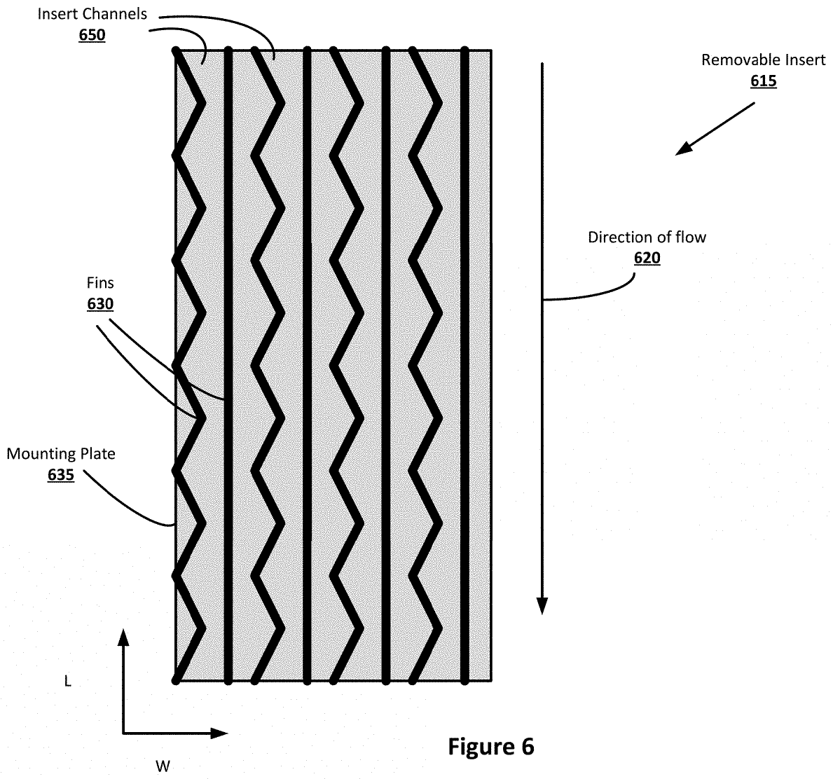

FIG. 6 depicts an alternative view of a removable insert 615, in accordance with various embodiments. The view of FIG. 6 may be similar to the view of FIG. 4, as described above. The removable insert 615 may include fins 630 and mounting plate 635, which may be similar to other fins and/or mounting plates described herein. In this embodiment, rather than having fins with the same profile as one another (such as may be seen, for example, in FIG. 4 or FIG. 5), the fins 630 may have different profiles from one another. Specifically, fins 630 with a zigzag profile may alternate with fins 630 having a linear profile. Such a profile may create localized sections in the insert channels 650 such that when liquid coolant flows through the insert channels 650 in accordance with the direction of flow 620, greater sections of coolant may be present in certain areas. This may allow for increased heat transfer as the coolant flows through the insert channels 650.

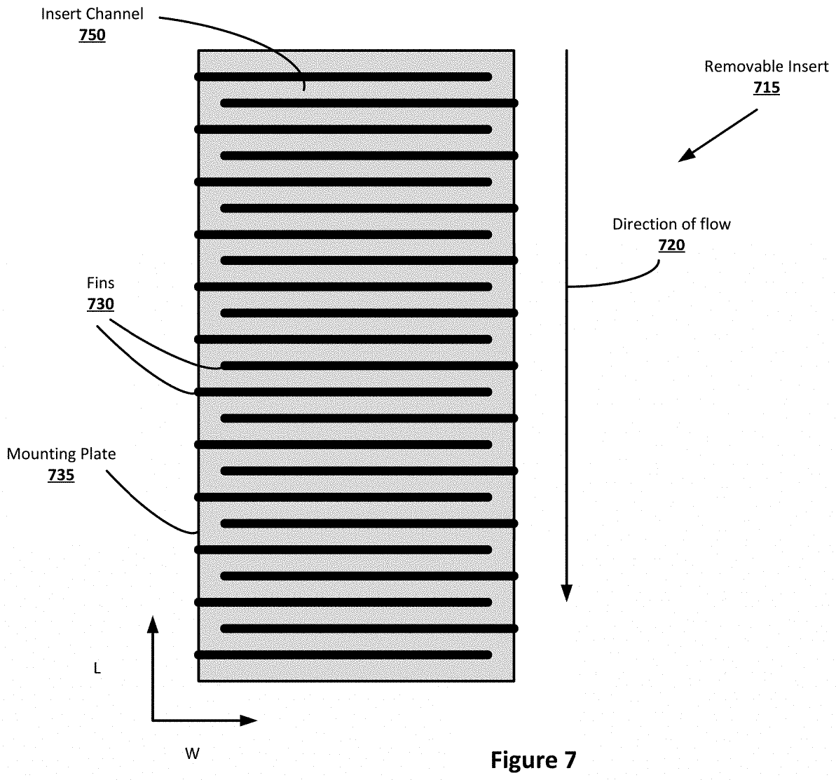

FIG. 7 depicts an alternative view of a removable insert 715, in accordance with various embodiments. The view of FIG. 7 may be similar to the view of FIG. 4, as described above. The removable insert 715 may include fins 730 and a mounting plate 735. In this embodiment, the fins 730 may form a single insert channel 750 through which fluid may flow in accordance with the direction of flow 720. Such an embodiment may be desirable to allow for more uniform heat transfer, or particular diode configurations.

It will be understood that the embodiments of FIG. 1 through FIG. 7 are intended as example embodiments to describe or discuss various characteristics of the present disclosure. Other embodiments may vary. For example, other embodiments may additionally or alternatively include more or fewer fins, fins with a different profile than depicted (e.g., fins with a sinusoidal-type profile), fins with different profiles than depicted with respect to one another, fins with a profile that changes over the length of the fin, etc.

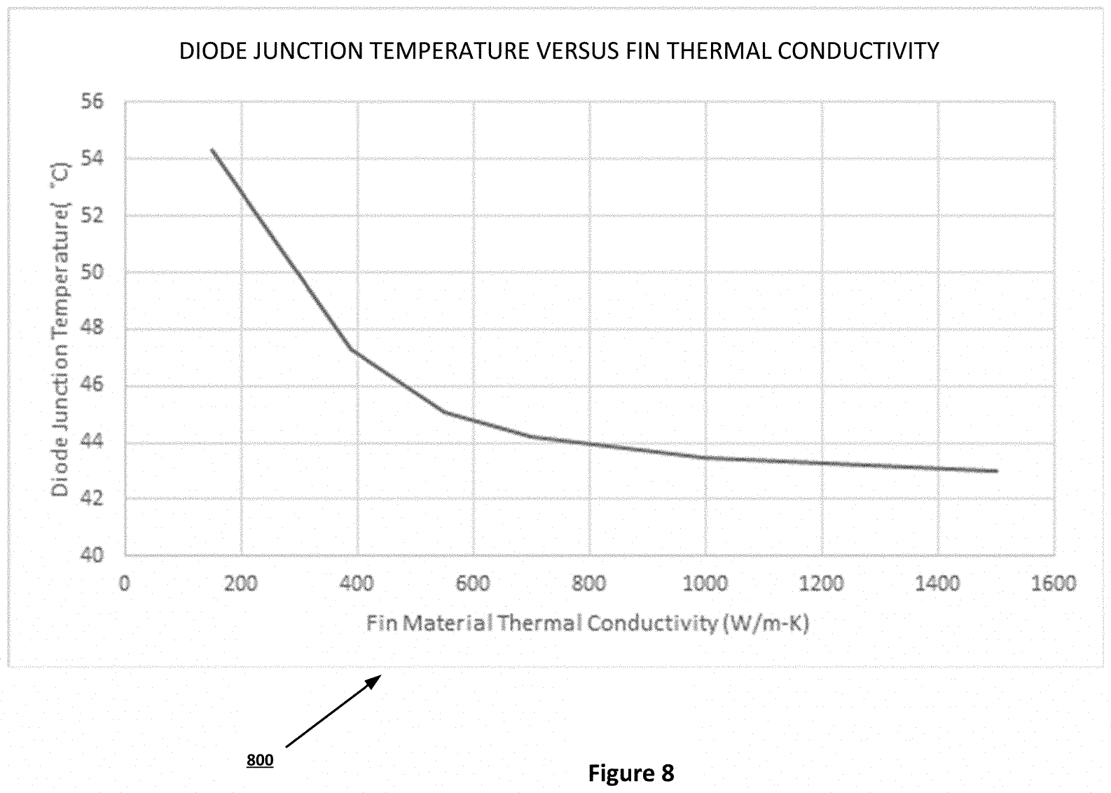

FIG. 8 depicts an example 800 of diode junction temperature versus thermal conductivity of a fin in a removable insert, in accordance with various embodiments. As may be seen, as fin material thermal conductivity increases along the X-axis, the diode junction temperature decreases as may be seen along the Y-axis. Therefore, it may be recognized that the use of fins with a material with a higher thermal conductivity, for example, one or more of the composite materials described above, may reduce the diode junction temperature seen at the heat sink. As described above, such a reduction may provide significant benefits with respect to the efficiency or functioning of the laser diode package.

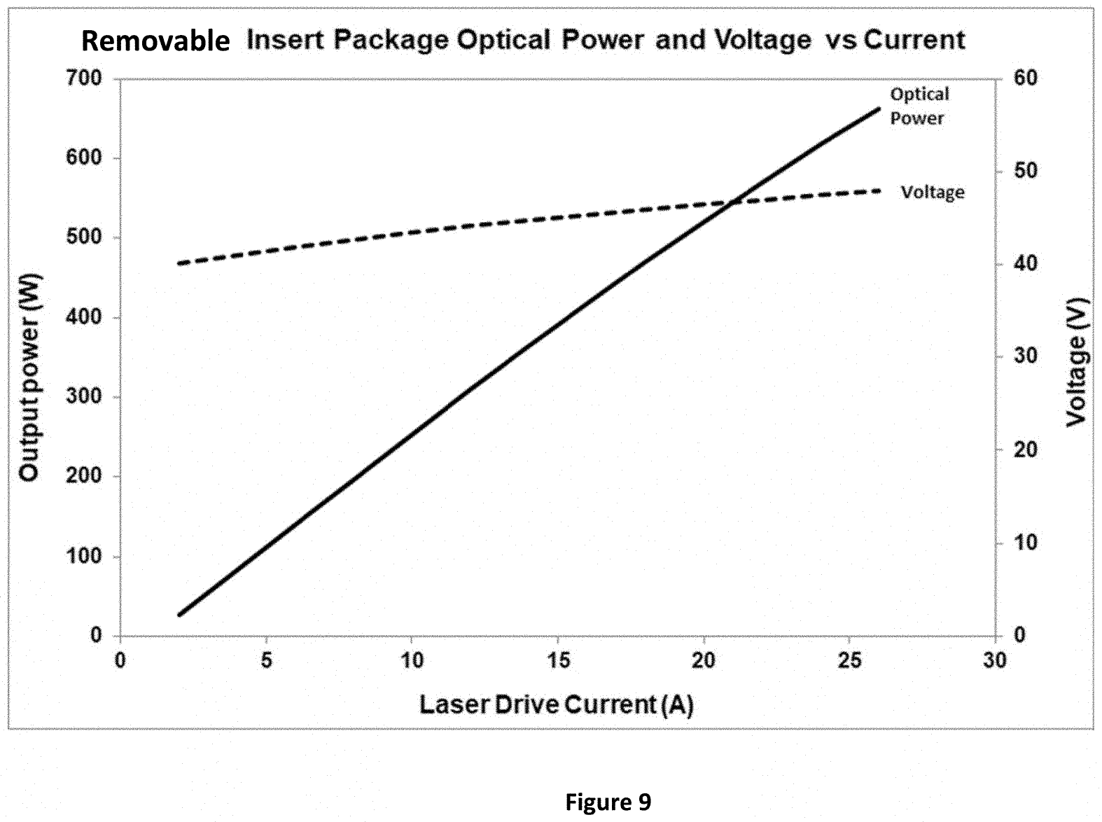

FIG. 9 depicts example test data related to a liquid-cooled laser diode package that includes a heat sink such as that pictured in FIG. 1 that includes one or more removable inserts such as removable inserts 115. In these embodiments, the heat sink body 100 may be formed of or include aluminum, while the removable inserts 115 may be formed of copper.

In FIG. 9, the X-axis depicts laser drive current in Amperes (A). Specifically, the X-axis depicts the current that is fed into the laser diode package to activate the laser diode. The left-side Y-axis depicts output optical power in W, which corresponds to the solid line depicted in FIG. 9. The output optical power corresponds to the amount of power output by the laser diode as a function of drive current. The right-side Y-axis depicts the Package Operating Voltage (V) as a function of drive current, which corresponds to the dashed line in FIG. 9.

As may be seen in FIG. 9, as the laser drive current increases, the output optical power increases generally linearly from approximately 10 W at a drive current of approximately 2.5 A to approximately 680 W at a drive current of approximately 26 A. By contrast, the Package Operating Voltage increases from a value of approximately 41 V at a drive current of approximately 2.5 A to approximately 48 V at a drive current of approximately 27 A. This increase in Package Operating Voltage as a function of drive current may be due to factors such as the series electrical resistance of the circuit of laser diodes within the package.

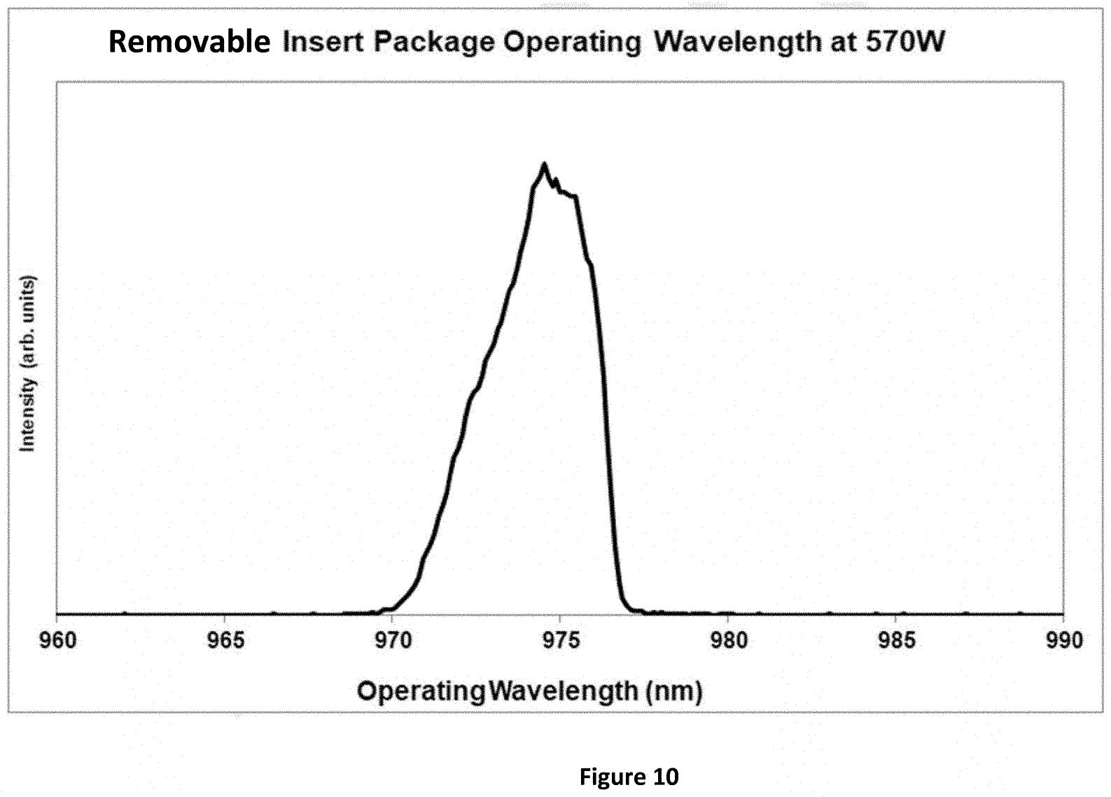

FIG. 10 depicts example test data related to a liquid-cooled laser diode package such as the laser diode package of FIG. 9, described above. Specifically, the Y-axis of FIG. 10 depicts the intensity of the output of the laser diode (units arbitrary for the purposes of this discussion). The X-axis of FIG. 10 depicts the operating wavelength of the output of the laser diode in nanometers (nm). As may be seen, the intensity between operating wavelengths of approximately 970 nm and approximately 978 nm may be relatively smooth and well-defined, while other operating wavelengths are relatively energy-free. As such, it may be understood that the heat sink with the removable insert may efficiently remove heat from the laser diode in a manner that does not cause energy to be present outside of the wavelength range as defined above. This lack of energy outside of the defined wavelength range may be interpreted as an indication of efficient heat removal from the laser diode with the understanding that the output wavelength is a function of the laser diode junction temperature, and that higher temperatures result in energy being present at longer operating wavelengths.

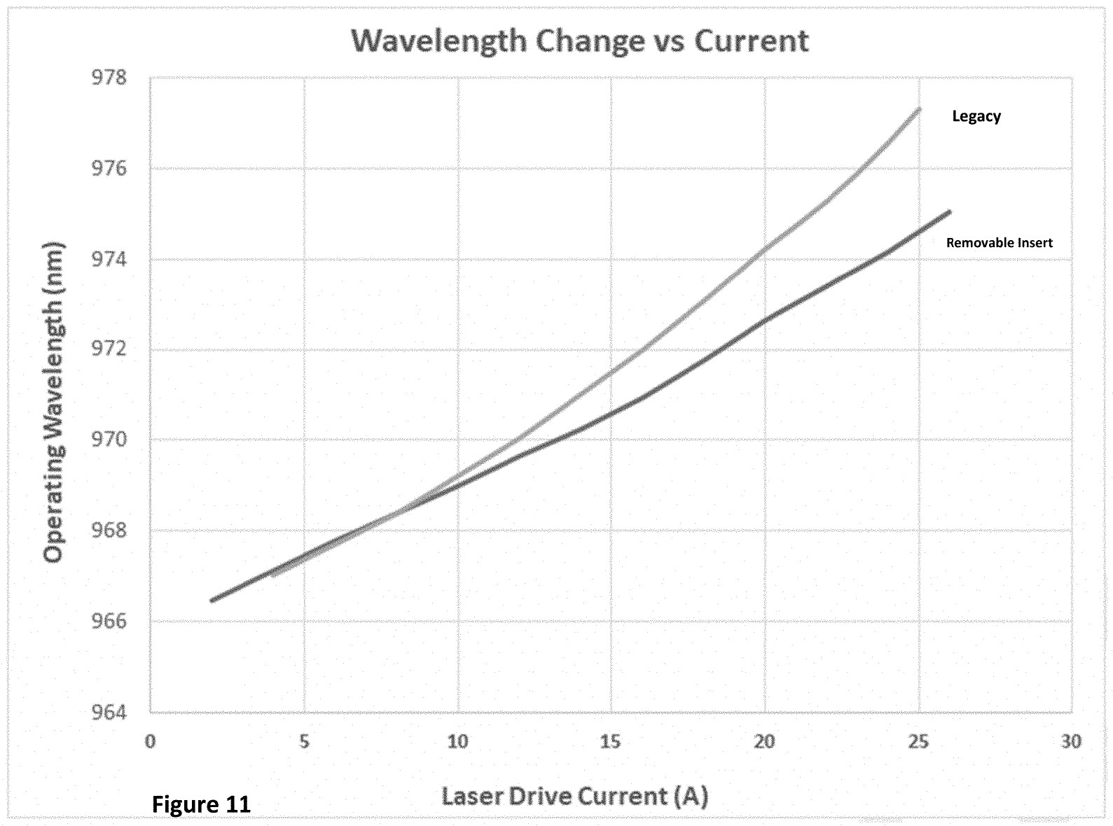

FIG. 11 depicts an example of test data related to wavelength change versus current of two laser diode packages, in accordance with various embodiments. Specifically, the first package (depicted by the darker black line that is labelled “removable insert” in FIG. 11) is related to a laser diode package with a heat sink that includes a removable insert, such as removable insert 115. The second package (depicted by the lighter grey line that is labelled “legacy” in FIG. 11) is related to a laser diode package that includes a legacy heat sink. The X-axis depicts the laser-drive current in amperes (A), and may be similar to the X-axis of FIG. 9. The Y-axis depicts the operating wavelength in nanometers (nm), and may be similar to the X-axis of FIG. 10.

Generally, wavelength versus current may be one way to compare thermal performance of different laser diode package designs. For the sake of this data, it may be assumed that the two laser diode packages have the same laser diode material system and epitaxial structure, and the same water flow and water temperature passing through the heat sink of the package. At an operating current of, for example, between approximately 20 A and approximately 24 A (which may be considered a typical operating current for some laser diode packages), it may be seen that the legacy package has an operating wavelength that is between approximately 1 nm and approximately 3 nm longer than the operating wavelength of the laser diode package that includes the removable insert. Based on the physical properties of the laser diode material composition in this example, this observed difference indicates that the temperature of the legacy laser diode package is between approximately 3 and approximately 9 degrees Celsius (° C.) hotter than the temperature of the laser diode package with the removable insert.

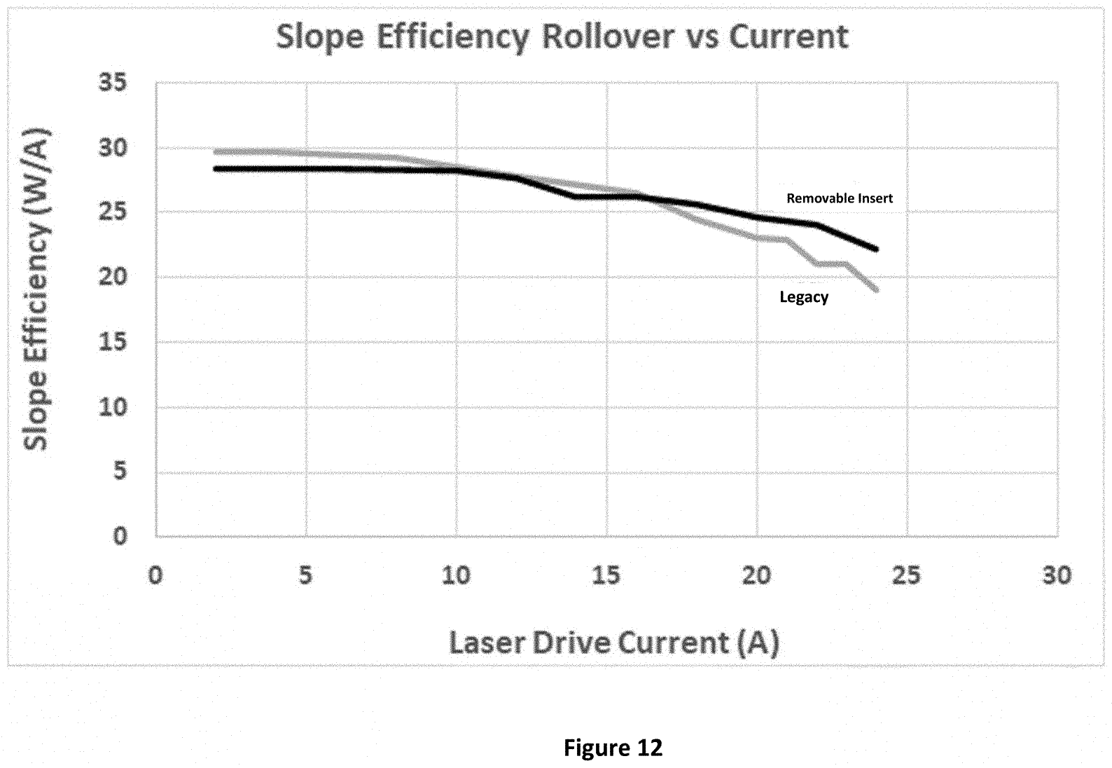

FIG. 12 depicts an example of test data related to slope efficiency rollover versus current. The Y-axis of FIG. 12 depicts slope efficiency data in units of Watts/Amperes (W/A). The X-axis depicts laser drive current of the laser drive package in units of amperes (A).

Data related to two different laser diode packages is depicted in FIG. 12. The first package is a legacy package, and is indicated by the lighter grey line that is labelled “Legacy.” The second package is a laser diode package with a removable insert such as removable insert 115, and is represented by the darker line that is labelled “removable insert.”

Generally, the slope efficiency of a laser diode package may change as a function of laser drive current, and may be one way of comparing thermal performance between two laser diode packages. A smaller W/A value may indicate a laser diode package that has lower optical power and efficiency than a package with a higher W/A value. This interpretation may be because a higher laser diode junction temperature (which may indicate a lower optical power and efficiency) may result in a lower W/A value. The rate at which the W/A value changes may also be an indicator of thermal performance of a laser diode package. Additionally, the amount of curvature for the plotted values of W/A, as the laser drive current increases, is correlated to the laser diode junction temperature, with a larger amount of curvature indicating a device whose performance is degrading at a faster rate than a device with a smaller curvature.

For each of these metrics, and particularly in the above-described operating range of between approximately 20 and approximately 24 A, it may be seen that the package with the removable insert outperforms the legacy package. For example, the package with the removable insert has a higher W/A value, a lower degree of change, and less curvature.

Some non-limiting examples of various embodiments are provided below.

Example 1 includes a heat sink configured to remove heat from at least one laser diode, wherein the heat sink comprises: a heat sink body configured to be filled with a cooling fluid, wherein the heat sink body includes a cavity; and a removable insert configured to be placed within the at least one cavity; wherein: the removable includes a mounting plate with a first side and a second side opposite the first side; the first side is configured to couple with the least one laser diode; the second side is coupled with a plurality of fins formed of a composite material with a thermal conductivity above 200 W/m-K; and the mounting plate, when the removable insert is placed within the at least one cavity, seals the heat sink body such that the cooling liquid can not exit the heat sink body from the cavity.

Example 2 includes the heat sink of example 1, and/or some other example herein, wherein composite material is a material that includes copper and diamond, a material that includes aluminum and diamond, or a material that includes aluminum and graphite.

Example 3 includes the heat sink of any of examples 1-2, and/or some other example herein, wherein the mounting plate is ceramic, diamond, copper, aluminum, graphite, or a material that includes copper and diamond.

Example 4 includes the heat sink of any of examples 1-3, and/or some other example herein, wherein the fins, when the removable insert is coupled with the heat sink body, form at least one channel through which the cooling fluid can flow with the heat sink body.

Example 5 includes the heat sink of any of examples 1-4, and/or some other example herein, wherein the first side of the mounting plate is configured to couple with between 1 and 20 laser diodes.

Example 6 includes the heat sink of any of examples 1-5, and/or some other example herein, wherein a fin of the plurality of fins is formed from a different composite material than another fin of the plurality of fins.

Example 7 includes the heat sink of any of examples 1-6, and/or some other example herein, wherein the laser diode is a laser diode that produces between 1 and 100 Watts (W) of power.

Example 8 includes a heat sink configured to remove heat from at least one laser diode, wherein the heat sink comprises: a heat sink body configured to be filled with a cooling fluid, wherein the heat sink body includes at least one cavity; and a removable insert configured to be placed within the at least one cavity; wherein: the removable insert includes a mounting plate with a first side and a second side opposite the first side; the first side is configured to couple with the least one laser diode; the second side is coupled with a plurality of fins formed of a composite material; and the fins define at least one channel through which the cooling fluid can flow when the removable insert is positioned within the at least one cavity.

Example 9 includes the heat sink of example 8, and/or some other example herein, wherein the mounting plate is ceramic, diamond, copper, aluminum, graphite, or a material that includes copper and diamond.

Example 10 includes the heat sink of any of examples 8-9, and/or some other example herein, wherein the composite material has a thermal conductivity of at least 200 W/m-K.

Example 11 includes the heat sink of any of examples 8-10, and/or some other example herein, wherein respective fins of the plurality of fins are parallel with one another with respect to a direction of fluid flow through the at least one channel.

Example 12 includes the heat sink of any of examples 8-11, and/or some other example herein, wherein at least one fin of the plurality of fins is not parallel with another fin of the plurality of fins with respect to a direction of fluid flow through the at least one channel.

Example 13 includes the heat sink of any of examples 8-12, and/or some other example herein, wherein the laser diode is a laser diode that produces between 1 and 100 W of power.

Example 14 includes the heat sink of any of examples 8-13, and/or some other example herein, wherein the first side of the mounting plate is configured to couple with between 1 and 20 laser diodes.

Example 15 includes an apparatus comprising: a heat sink that includes: a heat sink body configured to be filled with a cooling fluid, wherein the heat sink body includes at least one cavity; and a removable insert configured to be placed within the at least one cavity, wherein the removable insert includes a mounting plate with a first side and a second side opposite the first side, wherein the second side is coupled with a plurality of fins formed of a composite material with a thermal conductivity at or above 200 W/m-K and the plurality of fins define at least one channel through which the cooling fluid can flow when the removable insert is positioned within the at least one cavity; and at least one laser diode coupled with the first side of the mounting plate.

Example 16 includes the apparatus of example 15, and/or some other example herein, wherein composite material is a material that includes copper and diamond, a material that includes aluminum and diamond, or a material that includes aluminum and graphite.

Example 17 includes the apparatus of any of examples 15-16, and/or some other example herein, wherein the removable insert has a length, as defined in a direction parallel to the at least one channel, of between 10 and 150 mm.

Example 18 includes the apparatus of any of examples 15-17, and/or some other example herein, wherein the removable insert has a width, as defined in a direction perpendicular to the at least one channel, of between 5 and 25 mm.

Example 19 includes the apparatus of any of examples 15-18, and/or some other example herein, wherein the insert has a height, as defined in a direction perpendicular to the second side of the mounting plate, of between 1 and 5 mm.

Example 20 includes the apparatus of any of examples 15-19, and/or some other example herein, wherein the composite material is different than a material of the mounting plate.

Although certain embodiments have been illustrated and described herein for purposes of description, this application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

What is claimed is:

1. A heat sink configured to remove heat from at least one laser diode, wherein the heat sink comprises:
a heat sink body configured to be filled with a cooling fluid, wherein the heat sink body includes a cavity; and
a removable insert configured to be placed within the at least one cavity;
wherein:
the removable includes a mounting plate with a first side and a second side opposite the first side;
the first side is configured to couple with the least one laser diode;
the second side is coupled with a plurality of fins formed of a composite material with a thermal conductivity above 200 Watts per meter-Kelvin (W/m-K); and
the mounting plate, when the removable insert is placed within the at least one cavity, seals the heat sink body such that the cooling liquid can not exit the heat sink body from the cavity.

2. The heat sink of claim 1, wherein composite material is a material that includes copper and diamond, a material that includes aluminum and diamond, or a material that includes aluminum and graphite.

3. The heat sink of claim 1, wherein the mounting plate is ceramic, diamond, copper, aluminum, graphite, or a material that includes copper and diamond.

4. The heat sink of claim 1, wherein the fins, when the removable insert is coupled with the heat sink body, form at least one channel through which the cooling fluid can flow with the heat sink body.

5. The heat sink of claim 1, wherein the first side of the mounting plate is configured to couple with between 1 and 20 laser diodes.

6. The heat sink of claim 1, wherein a fin of the plurality of fins is formed from a different composite material than another fin of the plurality of fins.

7. The heat sink of claim 1, wherein the laser diode is a laser diode that produces between 1 and 100 Watts (W) of power.

8. A heat sink configured to remove heat from at least one laser diode, wherein the heat sink comprises:
a heat sink body configured to be filled with a cooling fluid, wherein the heat sink body includes at least one cavity; and
a removable insert configured to be placed within the at least one cavity;
wherein:
the removable insert includes a mounting plate with a first side and a second side opposite the first side;
the first side is configured to couple with the least one laser diode;
the second side is coupled with a plurality of fins formed of a composite material; and
the fins define at least one channel through which the cooling fluid can flow when the removable insert is positioned within the at least one cavity.

9. The heat sink of claim 8, wherein the mounting plate is ceramic, diamond, copper, aluminum, graphite, or a material that includes copper and diamond.

10. The heat sink of claim 8, wherein the composite material has a thermal conductivity of at least 200 Watts per meter-Kelvin (W/m-K).

11. The heat sink of claim 8, wherein respective fins of the plurality of fins are parallel with one another with respect to a direction of fluid flow through the at least one channel.

12. The heat sink of claim 8, wherein at least one fin of the plurality of fins is not parallel with another fin of the plurality of fins with respect to a direction of fluid flow through the at least one channel.

13. The heat sink of claim 8, wherein the laser diode is a laser diode that produces between 1 and 100 Watts (W) of power.

14. The heat sink of claim 8, wherein the first side of the mounting plate is configured to couple with between 1 and 20 laser diodes.

15. An apparatus comprising:
a heat sink that includes:
a heat sink body configured to be filled with a cooling fluid, wherein the heat sink body includes at least one cavity; and
a removable insert configured to be placed within the at least one cavity, wherein the removable insert includes a mounting plate with a first side and a second side opposite the first side, wherein the second side is coupled with a plurality of fins formed of a composite material with a thermal conductivity at or above 200 Watts per meter-Kelvin (W/m-K) and the plurality of fins define at least one channel through which the cooling fluid can flow when the removable insert is positioned within the at least one cavity; and
at least one laser diode coupled with the first side of the mounting plate.

16. The apparatus of claim 15, wherein composite material is a material that includes copper and diamond, a material that includes aluminum and diamond, or a material that includes aluminum and graphite.

17. The apparatus of claim 15, wherein the removable insert has a length, as defined in a direction parallel to the at least one channel, of between 10 and 150 millimeters (mm).

18. The apparatus of claim 15, wherein the removable insert has a width, as defined in a direction perpendicular to the at least one channel, of between 5 and 25 millimeters (mm).

19. The apparatus of claim 15, wherein the insert has a height, as defined in a direction perpendicular to the second side of the mounting plate, of between 1 and 5 millimeters (mm).

20. The apparatus of claim 15, wherein the composite material is different than a material of the mounting plate.
